(19) United States
(12) Patent Application Publication
(10) Pub. No.: US 2009/0301543 A1
(43) Pub. Date: Dec. 10, 2009

(54) Thin film solar cells with monolithic integration and backside contact

(75) Inventors: Damoder Reddy, Los Gatos, CA (US); Craig Leidholm, San Jose, CA (US); Brian Gergen, Mountain View, CA (US)

Correspondence Address: NOLD INTELLECTUAL PROPERTY LAW, 101 California Street, Suite 2450, San Francisco, CA, 94111, US

(73) Assignee: Solexant Corp., San Jose, CA (US)

(21) Appl. No.: 12/455,326

(22) Filed: Jun. 1, 2009

Related U.S. Application Data
(60) Provisional application No. 61/130,926, filed on Jun. 4, 2008.
(60) Provisional application No. 61/131,179, filed on Jun. 7, 2008.

(51) Int. Cl. H01L 31/042; H01L 31/18; H01L 21/28

(52) U.S. Cl. 136/244; 438/57; 438/609; 257/E21.158; 257/E31.126

(57) ABSTRACT

The present invention discloses novel thin film photovoltaic devices with monolithic integration and backside metal contacts and methods of making the devices.

The innovative approach described in the present invention allows for devices and methods of construction completely through thin-film processes. Solar cells in accordance with the present invention provide an increased output for large devices due to decreased current loss in the transparent conducting electrode.

### CROSS REFERENCE TO RELATED APPLICATIONS

This application claims priority to U.S. Provisional Patent Application Ser. No. 61/130,926 filed Jun. 4, 2008 and 61/131,179, filed Jun. 7, 2008 the contents of both are incorporated herein by reference.

### BACKGROUND OF THE INVENTION

Current solar energy technologies can be broadly categorized as crystalline silicon and thin film technologies; this invention concerns thin film solar films. Approximately 90% of the solar cells are made from silicon—single crystal silicon or polycrystalline silicon. Crystalline silicon (c-Si) has been used as the light-absorbing semiconductor in most solar cells, even though it is a relatively poor absorber of light and requires a considerable thickness (several hundred microns) of material. Nevertheless, it has proved convenient because it yields stable solar modules with good efficiencies (13-18%, half to two-thirds of the theoretical maximum) and uses process technology developed from the knowledge base of the microelectronics industry.

Second generation solar cell absorber technology is based on “thin films”, an art recognized term. Main thin-film technologies are amorphous silicon, copper indium gallium diSelenide (CIGS), and cadmium telluride (CdTe).

CdTe thin-film solar cells are very simple to make and have the potential to achieve the lowest manufacturing cost compared to all other solar cell technologies. CdTe solar cells with 16.5% efficiency have been demonstrated by NREL. The prior art constructs CdTe solar cells by depositing CdTe on 3 mm thick glass substrates and encapsulated with a second 3 mm cover glass. Thus they are produced by a slow, piece by piece, manufacturing process. These CdTe solar cells are also very heavy and are difficult to use for residential rooftop applications—one of the largest market segments of solar industry. Flexible solar cells are light weight making them suitable for residential roof top applications which are not accessible to CdTe on heavy glass substrates

More efficient substrate architecture with thin film technologies is needed. A number of companies such as Kaneka™, Sharp™, Schott Solar™ and Ersol™ are manufacturing amorphous silicon solar cells on glass substrates by adopting commercially proven CVD process to deposit a-Si originally developed for flat panel display manufacturing. Glass substrate equipment companies such as Applied Materials™ are offering turn-key systems to manufacture amorphous-Si solar cells on glass substrates.

The superstrate configuration is used to manufacture conventional CdTe and amorphous silicon solar cells on transparent substrates such as glass. Prior art thin-film solar modules built on glass substrates are monolithically integrated by using a combination of laser scribing and mechanical scribing processes to isolate cells and serially interconnect them. One of the main drawbacks of thin-film solar cells is the limited current generated by these cells/modules as all the current must pass through transparent conducting oxide which has limited conductivity. Thus the limitation of the maximum achievable current per module imposes serious limitations on the use of thin-film solar cells in large solar farm market by significantly increasing the balance of system costs. Backside metal contact techniques have been used for silicon solar cells to address this issue. However these techniques cannot be used for traditional superstrate thin-film solar cells built on glass substrates because it is difficult, if not impossible, to make backside contact for solar cells built on glass substrates.

The substrate configuration for solar cells is used when flexible substrates such as opaque metal foils or semitransparent polymeric substrates are used to make amorphous silicon, CIGS or CdTe solar cells. Solexant Corp. has disclosed novel ideas for back contact formation for CdTe substrate solar cells, see commonly assigned and copending U.S. Ser. No. 12/380,638, filed 2 Mar. 2009, the contents of which are incorporated herein by reference.

The prior art also discloses Insulating substrate architecture that combine monolithic integration and a method to connect the transparent conductor to the backside metal, see U.S. Pat. Nos. 5,626,686; 5,733,381; 5,421,908 and 5,928,439 the contents of which are all incorporated herein by reference. These designs only work with solar cells using insulating substrates. Those devices would not work with a conductive substrate; nor do they suggest a solution to the problems faced when considering a conductive substrate.

Conductive substrates have been utilized by the prior art, but no one has successfully integrated the conductive substrate with a serial interconnection and parallel current collection using thin film absorber materials for photovoltaic devices on flexible substrates. CIGS solar cells are commonly built on conducting substrates, but their interconnect architecture needs improvement. Some companies such as Odersun cuts rolls of these films into small 1 cm strips and attach them manually to create serial interconnection. This is a laborious and expensive process. Other prior art methods connect the transparent conductor to the back metal electrode creating vias through the absorber layer and filling it with a conductive paste to create an emitter wrap, see U.S. Pat. No. 7,276,724 and U.S. Patent Publication No. 2007/0186971, the contents of which are both incorporated herein by reference.

Thin film solar cells on insulating substrates using CdTe and similar absorber materials are known in the prior art, see McCandless, B. et al., U.S. Pat. No. 4,709,466 and Tyan, Y-S. et al. U.S. Pat. No. 4,207,119 the contents of which are both incorporated herein by reference. Amorphous silicon solar cells built on flexible metal foils by United Solar Systems Corporation™, see U.S. Pat. No. 6,803,513, the contents of which are incorporated herein by reference, use monolithic integration and suffer from low currents in these modules. To overcome the resistance limitation of the transparent conducting electrode the United Solar Systems Corporation™ uses a cumbersome and expensive process to attach thin metal wires to the surface of transparent conductor to minimize resistance losses. Metallic substrates having other serial interconnect architecture are also known in the art, see U.S. Pat. No. 5,468,988.

The present invention discloses a novel approach to create a thin-film solar cell with monolithic integration and backside metal contact. One advantage of the innovative approach described by the present invention allows for devices and methods of construction completely through thin-film processes. Solar cells in accordance with the present invention provide an increased output for large devices due to decreased current loss in the TCO layer.

### SUMMARY OF THE INVENTION

In one embodiment of the present invention there is claimed a photovoltaic device comprising a plurality of photovoltaic cells, said cells each independently comprise a transparent conducting electrode, a window layer, an absorber layer, a bottom electrode, a conductive substrate, and a back electrode, wherein said bottom electrode and said back electrode are on opposite sides of the substrate. In one embodiment the substrate has a plurality of vias extending through the substrate. In another embodiment the vias are insulated from the conducting substrate by a thin insulating layer inside the vias. In another embodiment the bottom electrode of a first cell and the back electrode of an adjacent cell are electrically connected through at least one first contact, wherein said at least one first contact extends through the via, and the first cell bottom electrode and said adjacent cell back electrode are not electrically connected through the conducting substrate. In another embodiment at least one first contact comprises a contiguous coating on a via wall. In another embodiment at least one first contact comprises a via filled with a conducting material. In another embodiment at least one cell is serially connected to an adjacent cell by at least one first contact, and wherein said at least one first contact makes electrical contact between the bottom electrode of said at least one cell and the back electrode of an adjacent cell. In another embodiment the back electrode comprises a scribe near a first contact, wherein said scribe extends through the back electrode, and said adjacent cell comprises a scribe in the bottom electrode, wherein said scribe is located near the first contact and extends through bottom electrode. In another embodiment a first scribe extends through the transparent conducting electrode, wherein said first scribe is located near the first contact. In another embodiment said first scribe extends through the transparent conducting electrode extends through the window layer, absorber layer and the bottom electrode layer. In another embodiment a second scribe extends through the transparent conducting electrode, wherein said second scribe is located near the first contact and on an opposite side from said first scribe. In another embodiment said second scribe extends through the window layer and the absorber layer. In another embodiment said first and second scribes are substantially parallel to each other. In another embodiment a plurality of second contacts, wherein said plurality of second contacts each independently make parallel contact between the transparent conducting electrode and the back electrode, wherein said plurality of second contacts are electrically insulated from the bottom electrode, and the bottom electrode is not electrically connected to the back electrode. In another embodiment said second contact and said back electrode are in electrical contact through a contiguous coating on a via wall. In another embodiment said second contact and said back electrode are in electrical contact through a via filled with a conducting material. In another embodiment there is a first contact to make a serial connection between at least two cells and a second contact to make a parallel connection within a cell. In another embodiment there is at least one first contact and a plurality of second contacts, wherein said first contact and said second contacts each independently comprise a thin layer of conductive material that extends through the substrate. In another embodiment there is at least one first contact and a plurality of second contacts, and a thin insulating layer disposed inside the first contact and/or the second contact. In another embodiment there is at least one first contact and a plurality of second contacts, and a thin barrier layer disposed inside the first contact via and/or the second contact via. In another embodiment a plurality of photovoltaic cells are connected in a non-linear arrangement.

In another embodiment of the present invention there is described a photovoltaic device comprising a plurality of photovoltaic cells, said cells each independently comprise a transparent conducting electrode, a window layer, an absorber layer, a bottom electrode, a insulating substrate, a back electrode, wherein said bottom electrode and said back electrode are on opposite sides of the substrate. In another embodiment the substrate has plurality of vias extending through the substrate. In another embodiment the bottom electrode of a first cell and the back electrode of an adjacent cell are electrically connected through at least one first contact, wherein said at least one first contact extends through the via. In another embodiment at least one first contact comprises a contiguous coating on a via wall. In another embodiment at least one first contact comprises a via filled with a conducting material. In another embodiment at least one cell is serially connected to an adjacent cell by at least one first contact, and wherein said at least one first contact makes electrical contact between the bottom electrode of said at least one cell and the back electrode of an adjacent cell. In another embodiment the back electrode comprises a scribe near a first contact, wherein said scribe extends through the back electrode, and said adjacent cell comprises a scribe in the bottom electrode, wherein said scribe is located near the first contact and extends through bottom electrode. In another embodiment there is a first scribe through the transparent conducting electrode, wherein said first scribe is located near the first contact. In another embodiment said first scribe through the transparent conducting electrode extends through the window layer the absorber layer and the bottom electrode layer. In another embodiment there is a second scribe through the transparent conducting layer; said second scribe is located near the first contact and on an opposite side from said first scribe. In another embodiment said second scribe extends through the window layer and the absorber layer. In another embodiment said first and second scribes are substantially parallel to each other. In another embodiment a plurality of second contacts, wherein said plurality of second contacts each independently make parallel contact between the transparent conducting electrode and the back electrode, wherein said plurality of second contacts are electrically insulated from the bottom electrode, and the bottom electrode is not electrically connected to the back electrode. In another embodiment said second contact and said back electrode are in electrical contact through a contiguous coating on a via wall. In another embodiment said second contact and said back electrode are in electrical contact through a via filled with a conducting material. In another embodiment there is a first contact to make a serial connection between at least two cells and a second contact to make a parallel connection within a cell. In another embodiment there is at least one first contact and a plurality of second contacts, wherein said first contact and said second contacts each independently comprise a thin layer of conductive material that extends through the substrate. In another embodiment there is at least one first contact and a plurality of second contacts, and a thin insulating layer disposed inside the first contact and/or the second contact. In another embodiment there is at least one first contact and a plurality of second contacts, and a thin barrier layer disposed inside the first contact via and/or the second contact via. In another embodiment a plurality of photovoltaic cells are connected in a non-linear arrangement.

The absorber layer of devices described herein comprises a material chosen from the group consisting of Group IV materials, Group II-VI compounds, Group III-V compounds, Group I-III-VI compounds and organic polymers. In another embodiment the absorber layer comprises a material chosen from the group consisting of silicon, amorphous silicon, crystalline silicon, microcrystalline silicon, germanium and SiGe. In another embodiment the absorber layer comprises a compound chosen from the group consisting of CdTe, PbSe, PbTe, SnSe, SnS and SnTe. In another embodiment the absorber layer comprises a compound chosen from the group consisting of GaAs and InP. In another embodiment the absorber layer comprises a compound chosen from the group consisting of CIS and CIGS. In another embodiment the absorber layer comprises CdTe, and the window layer comprises CdS.

In another embodiment of the present invention there is disclosed a process for making a photovoltaic device, comprising provide a substrate with a plurality of holes, deposit a metal electrode layer on each side of the substrate to create a bottom and back electrode, scribe a portion of the metal layer from the circumference of one or more of the holes to electrically isolate the hole from the bottom electrode, scribe the bottom and back electrode longitudinally to define adjacent cells, whereby the adjacent cells are in electrical contact with one another through at least one contact between a bottom electrode of one cell and a back electrode of an adjacent cell through at least one hole, said hole positioned between the bottom scribe and the back electrode scribe, and further comprising, deposit an absorber layer, and deposit a transparent conductor layer. In another embodiment there is disclosed coating some of the holes and filling some of the holes. In another embodiment there is disclosed scribing the transparent conducting electrode longitudinally across a cell on one side of a series interconnect via, and scribing the transparent conducting electrode longitudinally across a cell on the opposite side of the same series interconnect via, wherein said scribes are in close proximity to the series interconnect via, and said scribes remove the TCO layer. In another embodiment there is disclosed scribing the transparent conducting electrode longitudinally across a cell on one side of a series interconnect via, wherein said scribe is in close proximity to the series interconnect via, and said scribe removes the TCO layer, the window layer, the absorber layer and the bottom electrode layer, and further comprising scribing the back contact electrode on the opposite side of the same series interconnect via. In another embodiment there is disclosed scribing a circumferential area from the transparent conducting electrode down to the bottom electrode around a current collect via.

### BRIEF DESCRIPTION OF THE DRAWINGS

FIG. 1 shows a side view of a photovoltaic device having adjacent photovoltaic cells connected with a series interconnect device.

FIG. 2 shows a side view of a photovoltaic cell with a current collection via and a serial interconnect via.

FIG. 2A shows an expanded side view of a current collection via of FIG. 2 on an insulating substrate.

FIG. 2B shows a side view of a serial interconnect via on an insulating substrate.

FIG. 3 shows a partial side view of a photovoltaic cell with current collection vias.

FIG. 4 shows a partial side view of a photovoltaic device with adjacent photovoltaic cells connected with a serial interconnect via.

FIG. 4A shows a partial side view of a photovoltaic device with adjacent photovoltaic cells isolated at the transparent conducting electrode with a scribe pattern.

FIG. 5 shows a side view of a partial view of a series interconnect via connecting adjacent photovoltaic cells on a conducting substrate.

FIG. 6 shows a side view of a photovoltaic cell with a serial interconnect via and current collection vias on a conducting substrate.

FIG. 7 shows a top view and corresponding side view of a substrate for construction of a device of the present invention.

FIG. 8 shows a top view and corresponding side view of a substrate with holes for the current collection and series interconnect vias.

FIG. 9 shows a top view and corresponding side view after creation of the insulating layer.

FIG. 10 shows a top view and corresponding side view after the barrier layer deposition.

FIG. 11 shows a top view and corresponding side view after front and back electrode deposition.

FIG. 12 shows a top view and corresponding side view of a photovoltaic device having adjacent cells after the bottom electrode has been scribed to create adjacent cell isolation and the bottom electrode has been scribed to isolate current collect vias.

FIG. 13 shows a top view and corresponding side view after the absorber layer deposition.

FIG. 14 shows a top view and corresponding side view after the window layer deposition.

FIG. 15 shows a top view and corresponding side view after the transparent conducting electrode deposition.

FIG. 16 shows a top view and corresponding side view after creation of the front and rear photovoltaic cell isolation scribes.

FIG. 17 shows a photovoltaic device having a plurality of cells connected in a linear pattern.

FIG. 18 shows a photovoltaic device having a plurality of cells connected in a tile pattern.

FIG. 19 shows a photovoltaic device having a plurality of cells connected in a tile-orthogonal pattern.

FIG. 20 shows a photovoltaic device having a plurality of cells connected in an annular pattern.

### DETAILED DESCRIPTION OF THE EMBODIMENTS

Reference will now be made in detail to some specific embodiments of the invention including the best modes contemplated by the inventors for carrying out the invention. Examples of these specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In this specification and the appended claims, the singular forms “a,” “an,” and “the” include plural reference unless the context clearly dictates otherwise. Unless defined otherwise, all technical and scientific terms used herein have the same meaning as commonly understood to one of ordinary skill in the art to which this invention belongs.

By “photovoltaic device” as used herein it is meant a multilayered structure where in a working environment is capable of converting light into electricity. The invention described herein is suitable when constructing a solar cell using a substrate or superstrate configuration. The device may have any further structure necessary to practically utilize the device such as leads, connections, etc. By “said cells each independently comprise” as used herein it is meant that “cells” is the “plurality of cells” and each individual cell that makes up a plurality of cells can comprise the described layers.

As used herein “photovoltaic cell” is broadly defined as the part of the device capable of photoelectric conversion and is generally the smallest unit in a photovoltaic device. Herein a cell's boundaries are defined by the location of scribes present in the various electrode layers. Different embodiments of the present invention call for varying placement of the scribes and varying cell architecture. Preferably the cell is separated by a scribe in the bottom electrode layer and back contact electrode as defined further herein. In one preferred embodiment adjacent photovoltaic cells are separated by scribes in the bottom electrode near an interconnect via at an edge of a cell. Each photovoltaic cell preferably comprises a substrate, an electrode disposed on both (opposite) sides of the substrate, an insulating layer, a barrier layer, an absorber layer, a window layer and a transparent conducting oxide electrode layer. Non-limiting examples of materials suitable for photovoltaic cell layers disclosed herein may be found in Durstock, M. et al. “Materials for photovoltaics: symposium held Nov. 29-Dec. 2, 2004, Boston, Mass., USA: Symposium proceedings/Materials Research Society v. 836 (2005), the contents of which are incorporated herein by reference. The invention as described herein is also suitable for tandem photovoltaic cells. Suitable architecture for tandem devices useful with this invention are described in “Preparation and Characterization of Monolithic HgCdTe/CdTe Tandem Cells” Mater. Res. Soc. Symp. Proc. Vol. 836, p. 265-270 (2008), the contents of which are incorporated herein by reference. The invention contemplates that not each photovoltaic cell used in a photovoltaic device need be unique. They may be varied by layer structure, materials, shape, or other.

By “plurality of photovoltaic cells” it is meant at least two photovoltaic cells. Preferably the cells are arranged adjacent one another. The invention contemplates that any number of cells may be serially connected to one another and also provides novel architecture for the interconnection of photovoltaic cells. In a preferred embodiment the bottom electrode of one cell and the back electrode of its adjacent cell are not in electrical contact except for the serial interconnect via.

By “monolithic integration” it is meant joining a plurality of photovoltaic cells together.

Holes suitable to create the vias of the present invention are of types the “current collect via” and the “serial interconnect via”. By “via” it is meant that portion of the device that used to be a hole in the substrate that is now filled. “Via” may also refer to any other opening or structure in the device that may have been formed by another method other than starting with a hole. Substrate holes are first made in the substrate foil by punching, drilling or other means and their size may be the same or different, preferably the size is uniform between about 25-500 microns. In an alternative embodiment the current collection holes have a different size than the serial interconnect holes. Current collection holes may have a different size from one another, and serial interconnect holes may have a size different from one another. The invention contemplates that any shape hole will be suitable, square holes, triangle shaped holes, complex shaped holes, etc. A hole extends through the substrate. The pattern of holes on the substrate is preferably uniform, but may be any shape desired.

By “extends through the substrate” it is meant that the via or contact displaces substrate material for another from one surface of a substrate to the opposite surface

By “series interconnect via” it is meant a hole or via and termed “first contact” in some embodiments in a photovoltaic cell having electrical contact with an adjacent cell through an electrically conductive coating on the hole or via wall or an electrically conductive filling in the hole or via. “Serial” and “series” are used interchangeable herein. The invention contemplates that one “series interconnect via is used to connect adjacent arrays, but it is possible to use two or more series interconnect vias on the same array. Preferably the interconnect via is not in electrical contact with the TCO layer of a cell or adjacent cell and is thus electrically isolated. In one embodiment the isolation may be accomplished by scribing patterns on the TCO layer near and/or around the interconnect via. In addition, thin films may be deposited as insulators or plugs may be deposited as insulators on and/or in the interconnect via near the TCO layer to effect isolation.

By “serially interconnected” it is meant two cells, preferably adjacent, connected in series.

By “current collect via” it is meant a contact preferably comprising a via or hole, also “termed second contact” in the photovoltaic cell having contact from the back electrode to the TCO layer and is preferably connected in parallel to at least one other “current collect via”. This term is also referred to as “current collection hole(s)”.

The absorber layer used in conjunction with photovoltaic cells of the present invention comprises a film comprising a semiconductor compound capable of photoelectric conversion chosen from the group consisting of Group I-VI, II-VI, III-V and IV-VI compounds and Group IV semiconductors and organic semiconductors. Preferred is CdTe, and Mo is best suited for CdTe deposition due to better thermal matching. Deposition methods for the CdTe include closed-spaced sublimation (CSS), spray deposition (SD), screen printing and electrodeposition. Other absorber materials include I-III-VI compounds such as CIGS. CIGS is CuInₓGa₁₋ₓSe, where 0≦x<1 and included herein is the family of materials known in the art as CIGS including CIS, CISe, CIGSe, CIGSSe. Organic semiconductors suitable for use in the present invention include poly(3-hexylthiophene), or poly(3-octylthiophene) and others known in the art, see for example Drndic, M. et al. U.S. Published Patent Application No. 20070102694 filed Feb. 6, 2006 the contents of which are incorporated herein by reference. The absorber layer preferably has a thickness of between about 1-10 microns.

The window layer as used herein is designed to form a junction with the absorber layer used in conjunction with the instant invention preferably comprises an n-type material. Suitable window materials are CdS, CdSe, ZnS, ZnSe and oxysulfides. Currently CdS forms the best heterojunction with CdTe and is thus preferred. The window layer may have a thickness of 50-200 nm. The CdS may be deposited using a PVD process such as sputtering or evaporation.

Substrates used in accordance with the instant invention may comprise an insulating or conductive material. The substrate can be a conductive opaque metal foil (stainless steel, aluminum or copper), a flexible transparent polymer film (such as polyimide, a polyamide, a polyethersulfone, a polyetherimide, a polyethylene naphthalate, a polyester, etc.) or a rigid transparent glass (borosilicate or soda lime). Preferably the substrate is flexible. The thickness of the substrate can be any suitable size depending on desired end use but it is preferably 25-250 microns for flexible metal foils, 10-100 microns for flexible polymer films or 1-5 mm for glass.

The electrode layers according to the present invention comprise a transparent conducting electrode, and a bottom and back electrode, wherein the bottom and back electrode are preferably metal electrodes and located on opposite sides of the substrate. By “electrode on one side of a substrate” and “electrode on the opposite side” it does not mean that the electrode is necessarily disposed directly on the substrate as there may be intermediate layers between the electrodes and the substrate. Suitable materials for the metal electrodes include Mo, Ti, Ni, Al, Nb, W, Cr, and Cu as non-limiting examples. Preferred is Mo, Ti or Ni. The metal electrode layer thickness can range from 50 nm to 2,000 nm, more preferred is 250-2000 nm. The metal layer can be deposited by physical vapor deposition techniques known in the art. This does not limit the electrode layers to actually be disposed on the substrate surface. The transparent conducting electrode are usually n-type materials with good conductivity and high transparency in the visible spectrum and may comprise a material chosen from the group consisting of ZnO, ITO, SnO₂, Cd₂SnO₄, In₂O₃ or Zn₂SnO₄. Preferably ZnO is used for its optoelectronic properties and its mechanical, thermal and chemical stability. Two different transparent conducting electrode layers may be used in combination if desired and thus take advantage of differing properties of two different materials. The ZnO may also comprise nanowires as disclosed in U.S. Pat. No. 7,265,037 the contents of which are incorporated herein by reference.

The invention contemplates that various interface layers may be present in the photovoltaic cells to match adjacent layers crystal structure, microstructure, lattice constant, electron affinity/work function, thermal expansion coefficient, diffusion coefficient, chemical affinity and mobility, mechanical adhesion and mobility, interface stress, defect and interface states, surface recombination centers, etc. “Interface layer” as used herein is meant to include a layer or plurality of layers between the absorber layer and the window layer, or between the absorber layer and the bottom electrode. By definition an “interface layer” includes a single layer as well as a set of multiple layers which may be 1, 2, 3, 4, 5 or more layers. Each layer or layers may independently comprise a thin film, nanoparticles, sintered nanoparticles or a combination of one or more of the three. The invention contemplates that a plurality of interface layers comprising films with the same and/or different grain sizes as well as layers comprising nanoparticles, sintered nanoparticles and or thin films of different chemical compositions. Examples of materials suitable for an interface layer between an electrode layer and the absorber layer include those materials and layers disclosed in commonly assigned and copending U.S. Ser. No. 12/381,637 filed 13 Mar. 2009, the contents of which is incorporated herein by reference. In some embodiments it may be useful to include interface layers as taught in commonly assigned and copending U.S. Ser. No. 12/383,532, filed 24 Mar. 2009, the contents of which are incorporated herein by reference, especially between the absorber layer and the window layer.

Barrier layers suitable for the instant invention may comprise glass, nitrides, oxides, carbides or mixtures of the above and have a thickness of between 50-500 nm. Barrier layers are optional and provide an additional protection against contaminant diffusion. When an insulating substrate is used a barrier layer is preferably applied on the top oxide layer and not on the bottom oxide layer. When a conducting substrate is used the barrier layer is preferably applied on the top oxide layer and on the bottom oxide layer wherein the barrier layer material also coats the inside of the holes or vias thinly and substantially uniformly.

Insulating layer materials suitable for the instant invention include inorganic materials such as metal oxides, TiO₂, ZnO, CuO, Cu₂O, and oxides of zirconium, lanthanum, niobium, tin, indium, indium tin (ITO), vanadium, molybdenum, tungsten, strontium, etc. Also suitable are materials chosen from the group consisting of Group I-VI, II-VI, III-V and IV-VI compounds and Group IV semiconductors and organic semiconductors. By “thin insulating layer inside the vias” it is meant a layer having a thickness that may be as thick as the inside diameter of the hole or via. Preferably the thickness is less, preferably between 2-20 μm, more preferably 2-10 μm.

By “forming a layer” it is meant those steps for depositing, etching, reacting scribing or otherwise creating or adding to a layer, or acting on a layer already present which includes PVD, CVD, evaporation and sublimation. Suitable techniques for forming the layers disclosed herein include the roll to roll continuous process disclosed in commonly assigned and copending U.S. Ser. No. 12/380,638, filed 2 Mar. 2009, the contents of which are incorporated herein by reference.

By “scribe” it is meant a portion removed or cut away, when used as a noun usually by laser patterning. Scribing techniques suitable for use with the present invention include mechanical or laser.

By “surface treatment” it is meant to include the processes wet etching, dry etching, sputtering, reduction, electrochemical, heat treatments and ion milling. These examples are illustrative only and not exhaustive.

The invention contemplates that nanoparticles and/or sintered nanoparticles are useful in the photovoltaic cells of the present invention. Useful species in the present invention comprise compound semiconductors which include Group I-VI, II-VI, III-V and IV-VI compounds and Group IV semiconductors. This also includes I-III-VI compounds such as CIGS. CIGS is CuInₓGa₁₋ₓSe, where 0≦x<1 and included herein is the family of materials known in the art as CIGS including CIS, CISe, CIGSe, CIGSSe. Spherical nanoparticles used herein have a size between about 1-100 nm, preferably between about 2-20 nm. It is understood that the instant invention contemplates that “nanoparticles” as used herein is not limited to spherical or substantially spherical particles but includes various shaped nanostructures such as tetrapods, bentrod, nanowires, nanorods, particles, hollow particles, single materials, alloyed materials, homogeneous and heterogeneous materials. The size of the nanoparticles is variable but it is preferred that if the particle is an elongate structure, i.e. a nanorod, that the length of the nanorod have a maximum length of about 100 nm and have a maximum diameter of about 1-20 nm, preferably about 5 nm.

Nanoparticles or sintered nanoparticles according to the instant invention may have a core or core/shell or core/shell/shell, or core/shell/shell/shell construction. The core and/or the shell can be a semiconductor material including, but not limited to, those of the Group II-VI (ZnS, ZnSe, ZnTe, CdS, CdSe, CdTe, HgS, HgSe, HgTe, MgTe and the like) and III-V (GaN, GaP, GaAs, GaSb, InN, InP, InAs, InSb, AlAs, AlP, AlSb, AlS, and the like), Group IV-V compounds, and IV (Ge, Si) materials, and an alloy thereof, or a mixture thereof. Type II heterostructures (see S. Kim, B. Fisher, H. J. Eisler, M. Bawendi, Type-II quantum dots: CdTe/CdSe(core/shell) and CdSe/ZnTe(core/shell) heterostructures, J. Am. Chem. Soc. 125 (2003)11466-11467, the contents of which are incorporated herein by reference) and alloyed quantum dots (X. H. Zhong, Y. Y. Feng, W. Knoll, M. Y. Han, Alloyed ZnₓCd₁₋ₓS nanocrystals with highly narrow luminescence spectral width, J. Am. Chem. Soc. 125 (2003) 13559-13563 and R. E. Bailey, S. M. Nie, Alloyed semiconductor quantum dots: tuning the optical properties without changing the particle size, J. Am. Chem. Soc. 125 (2003) 7100-7106, the contents of both are incorporated herein by reference) are considered suitable. The nanoparticles or sintered nanoparticles may have coatings or ligands attached thereto. Most of the materials listed above are quantum confined. But the invention does not require that the nanoparticles be quantum confined.

By “electrically insulating it is meant” having a resistance of at least 10 kohms/square.

By “electrically conductive” it is meant having a resistance less than 100 ohm/square.

In one embodiment a photovoltaic device may be manufactured by providing a substrate and creating a set of holes therein. A set of these holes will be used for serial interconnection and another set of holes will be used to make contact with the transparent conductor electrode and the backside electrode (current collection vias). If a conducting substrate is used the holes are created first followed by the creation of an insulating layer on the front surface, back surface and the walls of the holes (this step will not be necessary if an insulating substrate is used). A conducting metal layer is deposited on the front surface and back surface in such a way that the metal layer covers both front and rear surfaces and also makes contact between the front and back metal through the serial interconnect via and current collection via, either by filling them completely (filled via) or by coating the side walls (coated via). The bottom electrode metal and the back contact electrodes are scribed with a laser to create the neighboring cell isolation. Bottom electrode scribes and back contact electrode scribes are offset around the serial interconnect vias to allow serial connection of adjacent cells. Metal around the current collection via is removed by laser scribing the bottom electrode metal around these holes to isolate them from making contact with the contiguous front metal surface within a cell. If current collection vias are coated vias then the interface layer(s), absorber layer, window layer(s) and TCO are then deposited and scribed to isolate cells. If current collection vias are filled vias then interface layer(s), absorber layer and window layer(s) are then deposited and areas are scribed (mechanical or laser) to remove these layers on and around the current collection vias to expose the filled vias. A transparent conducting oxide layer is then deposited and subsequently scribed to isolate adjacent cells.

The invention is described below with particular reference to the Drawings. The embodiments, materials and ranges stated below are illustrative embodiments only and are not meant to be limiting or exhaustive unless otherwise indicated.

### EXAMPLE 1

### A Thin-Film CdTe Solar Cell on a Flexible Insulating Substrate with Serial Interconnects and a Back Metal Contact

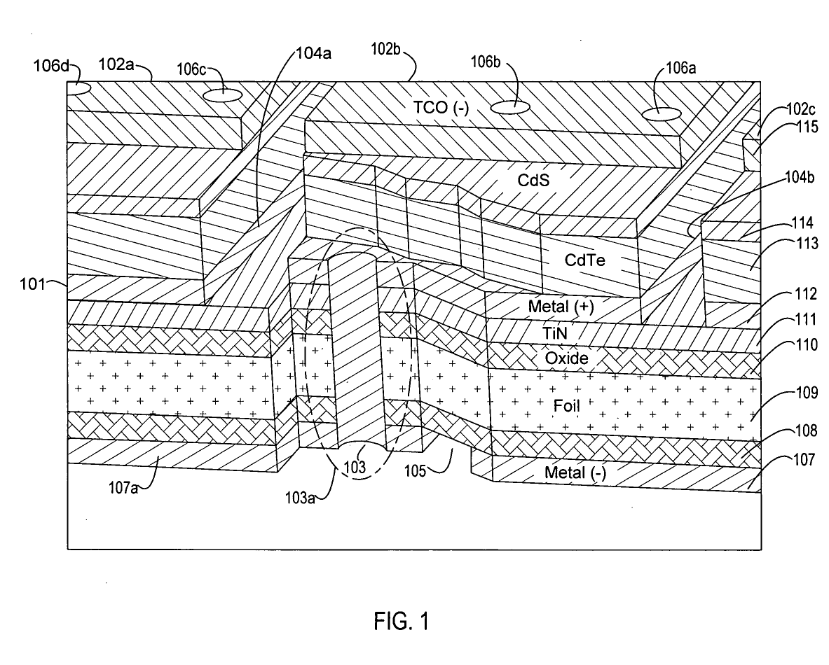

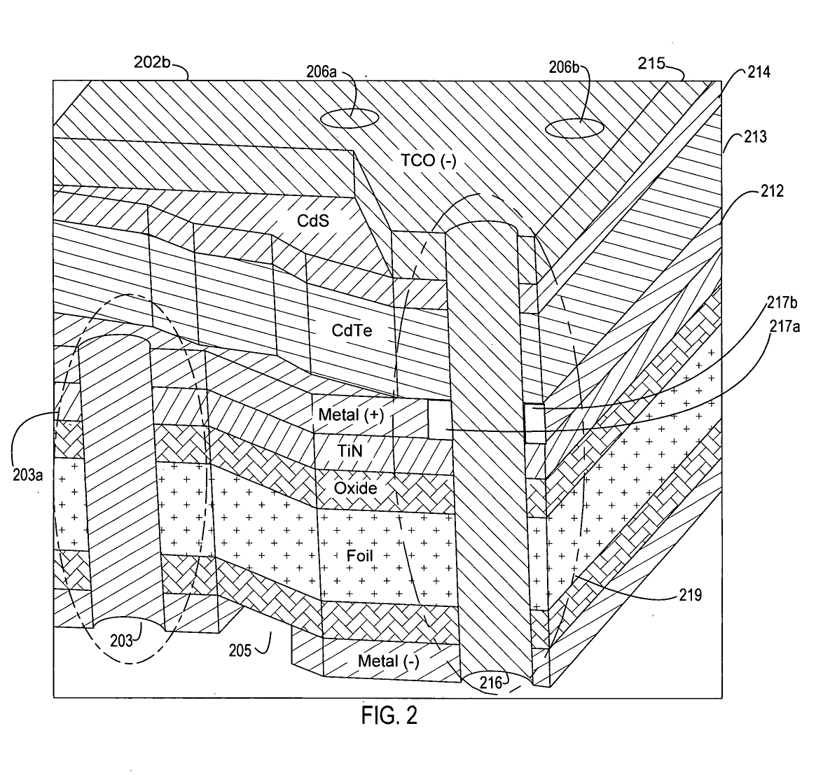

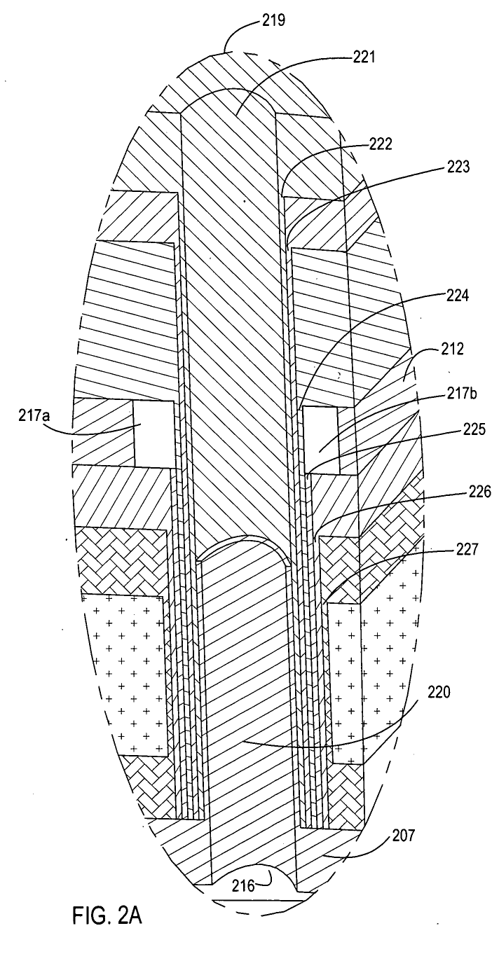

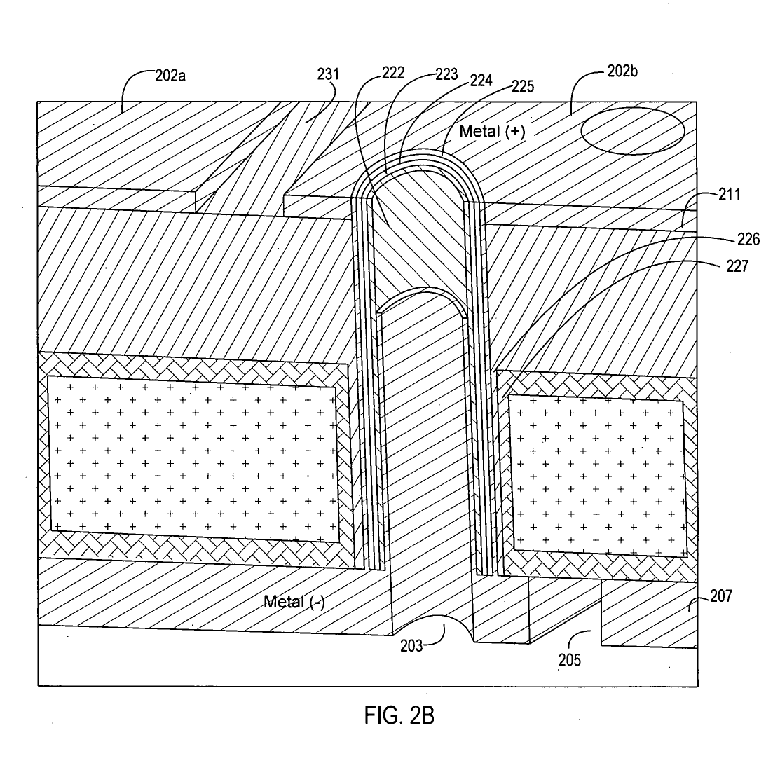

With reference to FIG. 1 there is shown a cross section of a photovoltaic device 101 in accordance with one embodiment of the present invention. Photovoltaic cells 102a, 102b and 102c are shown and adjacent cells 102a and 102b are interconnected with a serial interconnect via 103. Detail of via 103a is expanded in FIG. 2B. Scribes 104a and 104b separate photovoltaic cells 102a and 102b. Scribe 104a through the bottom electrode 112 in conjunction with scribe 105 in the back contact 107 serve to electrically isolate adjacent cells, connected by interconnect via 103. Scribe 104a is near via 103 and isolates via 103 from electrical contact with cell 102a bottom electrode, but makes electrical contact with cell 102a via an electrical contact with the bottom electrode of cell 102b through via 103 contact(not shown) to the back electrode 107a of cell 102a. Holes 106a and 106b define the top of the current collection vias (not shown) that make electrical contact with the back electrode layer 107. In FIG. 1 each cell has a layer structure as follows: a back metal electrode 107, a lower oxide layer 108, a substrate 109, a top oxide layer 110, a barrier layer 111, a bottom electrode 112, an absorber layer 113, a window layer 114 and a front electrode (transparent conductor layer or transparent conducting electrode) 115 and was made according to the process described in Example 2.

### EXAMPLE 2

### A Thin-Film CdTe Solar Cell on a Flexible Insulating Substrate with Serial Interconnects and a Back Metal Contact with Filled Vias

A process for manufacturing a solar cell in accordance with the present invention is described with particular reference to FIGS. 1-3. An insulating substrate 109 is provided with a plurality of holes 106a, 106b, 106c and 106d having a set of diameters. The holes may be created by any manner suitable depending on the material and size, shape and number of holes. The distance between the holes is variable. In one embodiment serial interconnect holes are punched 10 cm apart transversely on a foil in rows separated 100 cm apart in the orthogonal or longitudinal direction. Rows of current collection holes are punched in between the rows of serial connection holes at a separation of 1 cm in both the x and y directions. It is preferable to minimize the distance between the current collect vias to minimize resistance but to also minimize the number of contacts so as to ensure that the effective current producing area is not diminished.

Optionally, the substrate 109 is coated on the top side with a 50-500 nm thick top oxide layer 110 such as SiO₂, and on the bottom side with a bottom oxide layer 108 to prevent any contaminants from the substrate diffusing into active layers.

A 50-500 nm thick optional barrier layer 111 can be optionally deposited on the top oxide layer 110 to provide additional protection against contaminant diffusion. Titanium nitride is preferred. A conducting metal is deposited on the front and back surfaces to create bottom electrode layer 112 on top of the barrier layer 111 (if present) and back electrode layer 107 attached to the bottom oxide layer 108 and on the opposite side of the substrate 109. A preferable electrode material is Mo having a thickness between about 50-2,000 nm. In one embodiment contact is also made between the back electrode layer 107 and the bottom electrode 112 through the via 203 by either filling the vias completely or coating the side walls (not shown). The back electrode layer 107, 207 and the bottom electrode 112, 212 may be scribed 105, 205 on either side of the serial interconnect via 103, 203 to create neighboring cell isolation. This isolates the back metal electrode of adjacent cells from each other.

An absorber layer 113, 213 comprising CdTe having a thickness of 1-10 micron is deposited on the bottom electrode layer 112, 212. The bottom electrode layer 112, 212 is scribed 217a, 217b, 317a, 317b to define an area around the current collection hole 216 such that the via or any materials deposited on the sidewalls thereof are electrically isolated from the bottom electrode 112. In one embodiment interface layers (not shown) comprising materials such as ZnTe can be deposited at a 50-500 nm thickness on the bottom electrode layer 112 before depositing the absorber layer 113. In one embodiment the absorber layer 113 can be deposited by sputtering or other physical vapor deposition (PVD) methods known in the art for this purpose, such as close space sublimation (CSS), vapor transport deposition (VTD), evaporation, close-space vapor transport (CSVT) or by chemical vapor deposition (CVD) methods.

FIG. 2 is a more complete view of cell 102b in FIG. 1 having other features not shown in FIG. 1. Continuing with the process of making photovoltaic cell 202 having current collection via 216 and serial interconnect via 203 and current collection holes 206a and 206b, a window layer 214 having a thickness of between about 50-200 nm is deposited on the absorber layer 213.

With reference to FIG. 2 a transparent conducting electrode 215 comprising an oxide such as ZnO having a thickness of about 100-1000 nm is deposited on the window layer 214. The transparent conducting electrode 215 contacts the metal in the current collection holes and creates the back contact. Finally, the ZnO and back electrode are scribed 205 to define the series connected cells with backside metal contact.

Expanded view 219 of via 216 is shown in FIG. 2A and details the coatings on the current collection via 216. The deposition processes for the device produces a layered structure inside the via. The back metal electrode 207 deposition process produces a via 216 inner wall coating 220 of an electrically conductive material. Moving outward from the via inner chamber there is a transparent conductor layer 221 that extends all the way down to and makes electrical contact with the back metal electrode layer 207. In some embodiments coating 220 could just make contact with via coating 222 of the transparent conductor layer and the coating layer 221 does not need to extend to the back electrode 207 to make electrical contact. Via layer 225 (and thus the bottom electrode) is electrically isolated from the current collect via 216 by scribes 217a and 217b that define an electrically insulating area around the current collection tube, insulating it from bottom electrode 212. Also insulating current collect via 216 is via wall layer 224 of an absorber material and layer 223 comprising a window layer. Note that scribes 217a and 217b as shown are actually two ends of a cross section of one annular scribe. In one non-limiting embodiment the scribe is 100 microns wide from the outer periphery of the current collection holes. The size of the scribe is an obvious engineering variant depending on the materials used, shape of the via, and other factors.

Detail 203a of via 203 is shown in FIG. 2B. FIG. 2B shows an expanded view of a serial interconnect via of 103a and 203a on an insulating substrate. Serial interconnect via 203 connects two adjacent photovoltaic cells 202a and 202b separated by scribe 231 in the bottom electrode 211 and scribe 205 in the back metal electrode 207. The via 203 has a thin layer of oxide material 227, a barrier layer 226 and a metal layer 225. The top cut away view of via 203 also shows via inner layers 222, 223 and 224 comprising, respectively a transparent conductor material, a window material and an absorber material. Contact is made from the bottom electrode of cell 202b to the back electrode layer 207 of cell 202a through the via coating 225 which is electrically contacted to electrode 207 on the left side of the isolation scribe 205. Via wall layers 226 and 227 help to reduce diffusion contamination during processing.

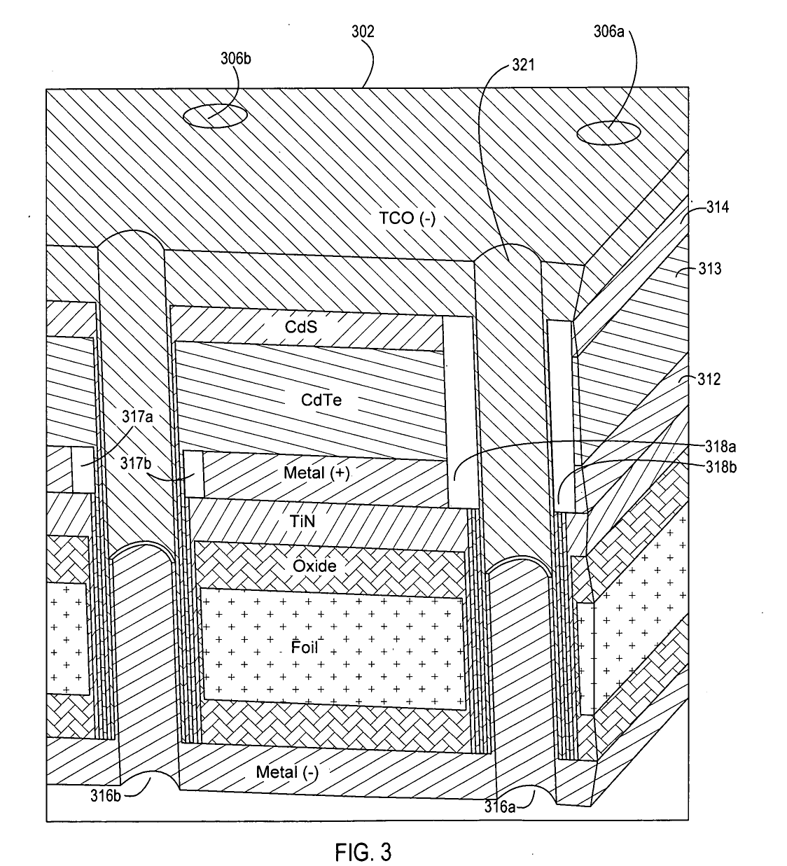

FIG. 3 shows a cross section of two current collection vias 316a and 316b connected in parallel in a photovoltaic cell 302 having current collection via openings 306a and 306b that define the top of their respective current collection vias (not shown) showing alternative embodiments for scribes to isolate the current collection vias from the bottom electrode layer. Scribes 317a and 317b circumferentially insulate the current collection via 316b from the bottom electrode 312. In an alternative embodiment the window layer 314, absorber layer 313 and the bottom electrode layer 312 layers are scribed 318a and 318b around the current collection holes to open up the contact area 318a and 318b which shows a scribe that extends around the current collection via 316a. The invention contemplates that one or both scribe architectures are suitable for use in the same device simultaneously.

### EXAMPLE 3

### A Thin-Film CdTe Solar Cell on a Flexible Conducting Substrate with Serial Interconnects and a Back Metal Contact

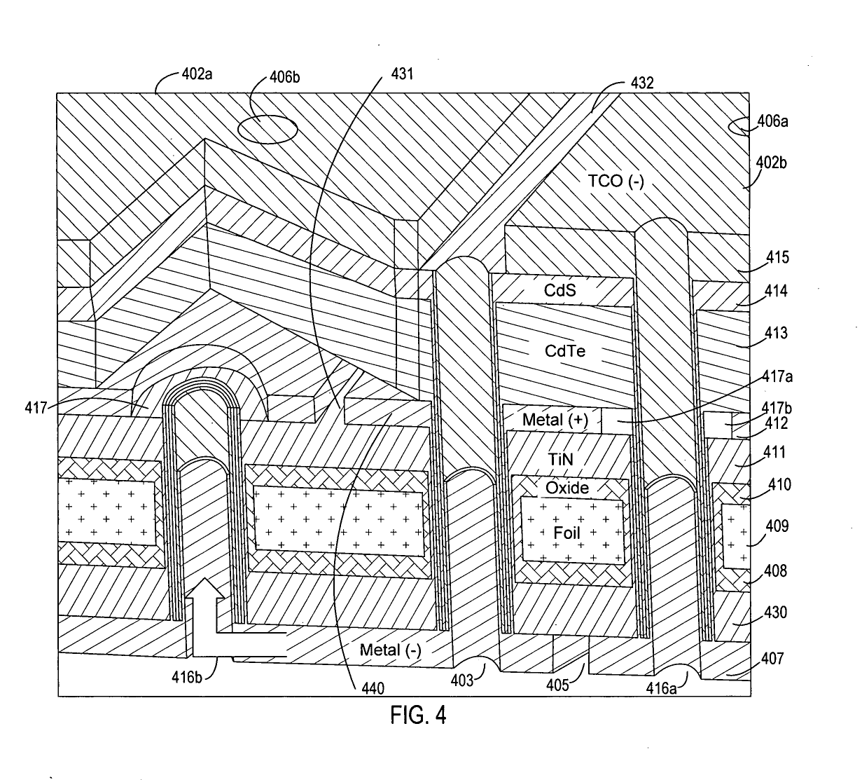

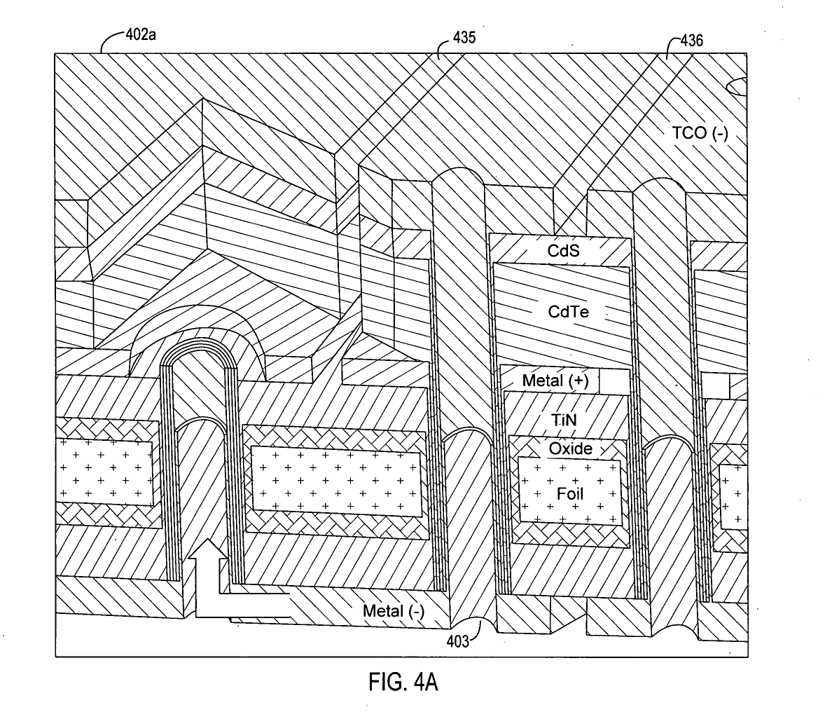

With reference to FIG. 4 there is disclosed a photovoltaic device designed in accordance with one embodiment of the present invention having photovoltaic cell 402a and adjacent photovoltaic cell 402b connected by serial interconnect via 403. Each cell 402a and 402b preferably has at least the following layer structure in order from bottom to top: a back metal electrode 407, a lower barrier layer 430, a lower oxide layer 408, a substrate 409, a top oxide layer 410, a top barrier layer 411, a bottom electrode 412, an absorber layer 413, a window layer 414 and a transparent conductor layer 415. Holes 406a and 406b define the openings at the top of current collection vias 416a and 416b respectively. Current collection vias 416a and 416b are in adjacent photovoltaic cells 402b and 402a respectively and serially interconnected by serial connection via 403. Back electrode 407 scribe 405 and bottom electrode 412 scribe 431 divide adjacent cells. Transparent conductor layer 415 has scribe 432 to isolate the serial interconnect via(s) 403 (and other interconnect vias not shown) and define adjacent cells. Current collection via 416a has annular scribe 417a and 417b through the bottom electrode layer 412 to isolate the vias 416a and 416b from the bottom electrode 412. In one embodiment scribe 417a is approximately 100 microns wider than the inside diameter of the via after deposition of the bottom electrode layer. Current collection via 416b has annular scribe 417 through the metal layer 412 to isolate the via from the bottom electrode 412.

In the embodiment shown in FIG. 4 “a photovoltaic cell” is defined with reference to three scribes. Scribe 432 separates the top part of cells 402a and 402b through the transparent conductor electrode. Scribe 431 separates cells 402a and 402b at the bottom electrode. When, as in this embodiment the scribe 432, 431 through the transparent conductor layer 415 and the bottom electrode layer 412 are offset, i.e. the scribes do not connect, an area 440 is created in the bottom electrode layer. This area and the area above, depending on the width of scribe 432 is capable of photoelectric conversion and increase the yield of the cell. Thus in this embodiment it is advantageous to make the scribe 432 as thin as practicable. It one embodiment it is preferred to place scribe 435 and 436 as close as possible to each other and to the via 403.

FIG. 4A shows an alternative embodiment of the present invention where the serial connect via 403 is isolated using scribe 435 which extends through the transparent conductor layer, the window layer, the absorber layer and the bottom electrode and scribe 436 which extends through a single transparent conductor layer, but optionally may extend through multiple layers including the window layer, the absorber layer and any present interface layers, but preferably not through the bottom electrode layer.

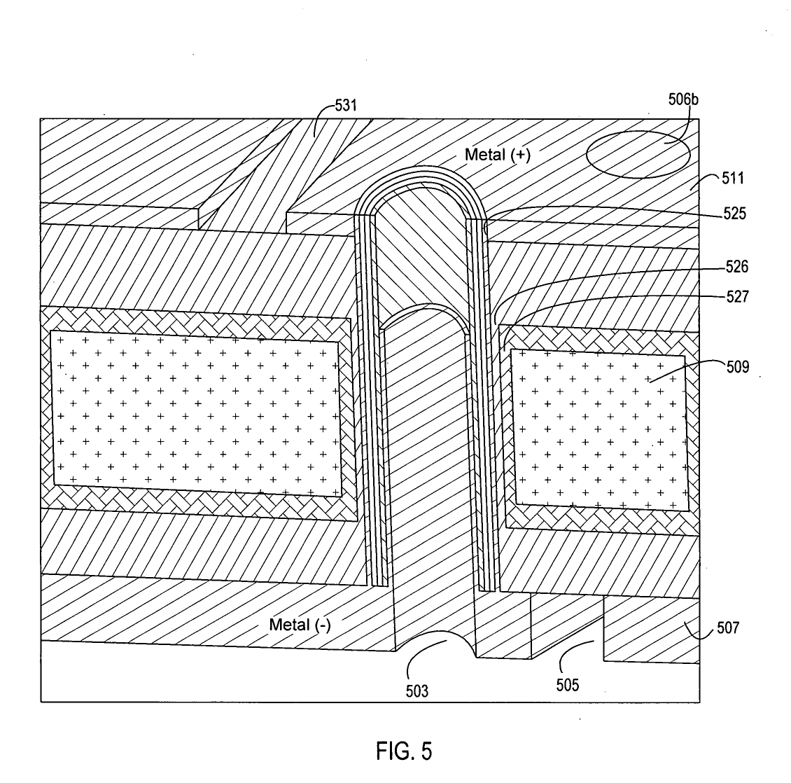

FIG. 5 shows an expanded view of a serial interconnect via 403 of FIG. 4. Serial interconnect via 503 connects two adjacent photovoltaic cells separated by scribe 531 in the bottom electrode 511 and scribe 505 in the back metal electrode 507. The via has a thin layer of insulating material 527, a barrier layer 526 and metal layer 525.

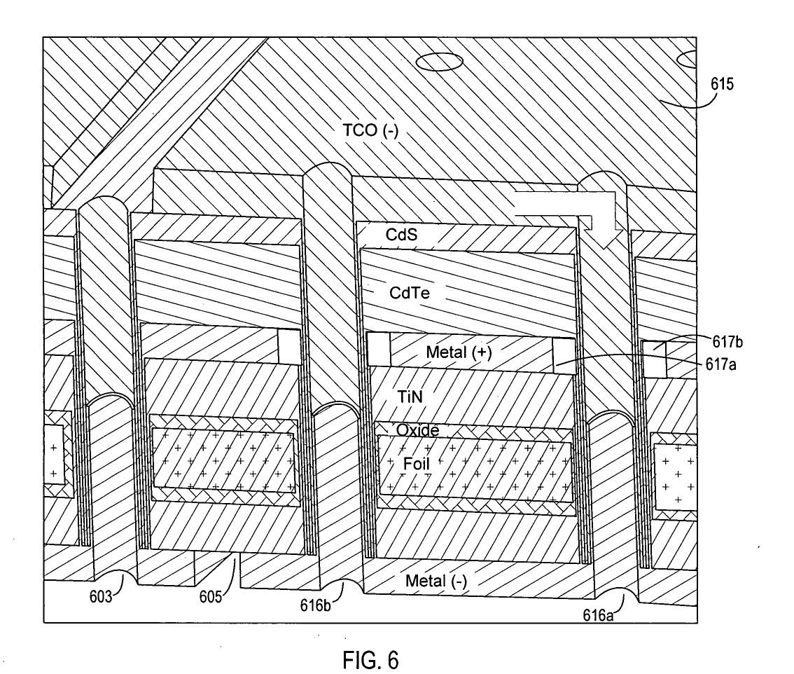

FIG. 6 shows another embodiment of a current collection scheme on the device of FIG. 4. Current collection vias 616a and 616b are electrically isolated from the front electrode by circumferential scribes 617a and 617b. Scribe 632 creates a channel to isolate the serial interconnect via 603 from the transparent conductor layer 615.

### EXAMPLE 4

### A Method of Making a Thin-Film CdTe Solar Cell on a Flexible Conducting Substrate with Serial Interconnect and the Back Metal Contact

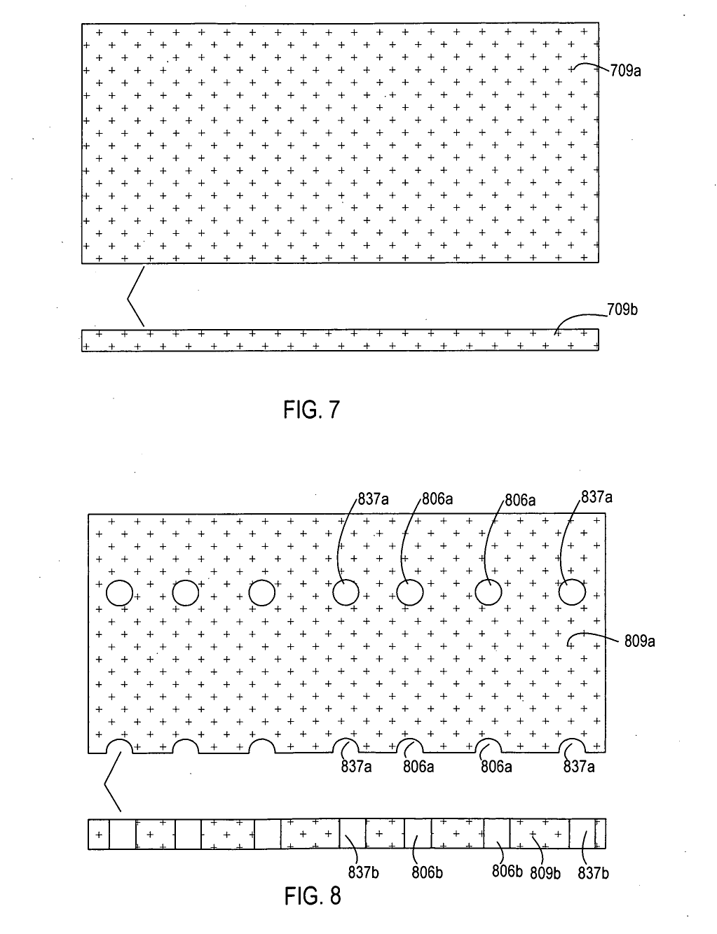

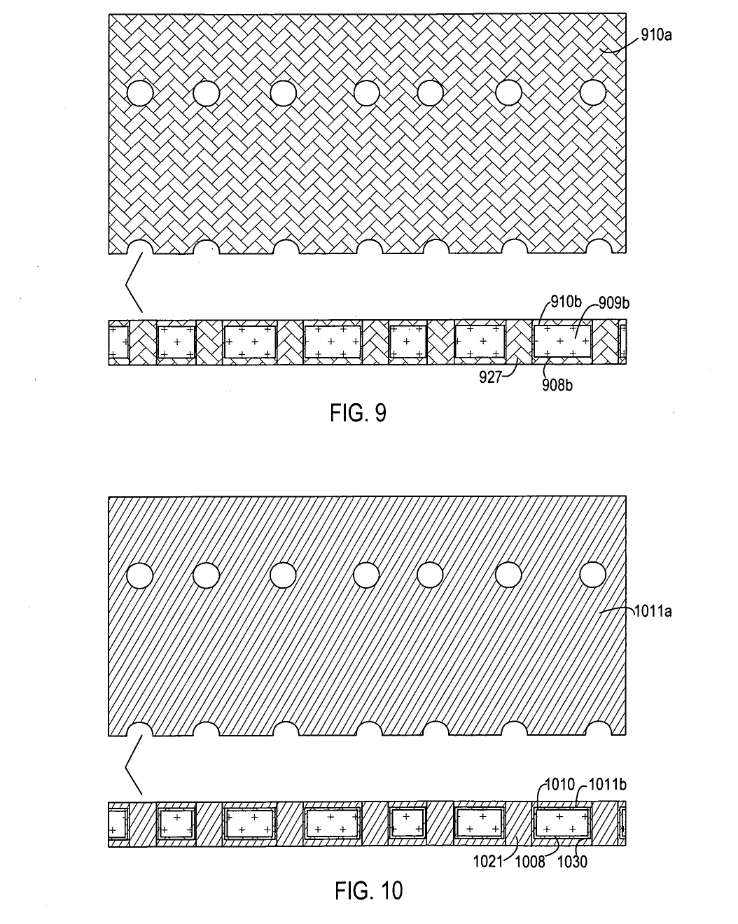

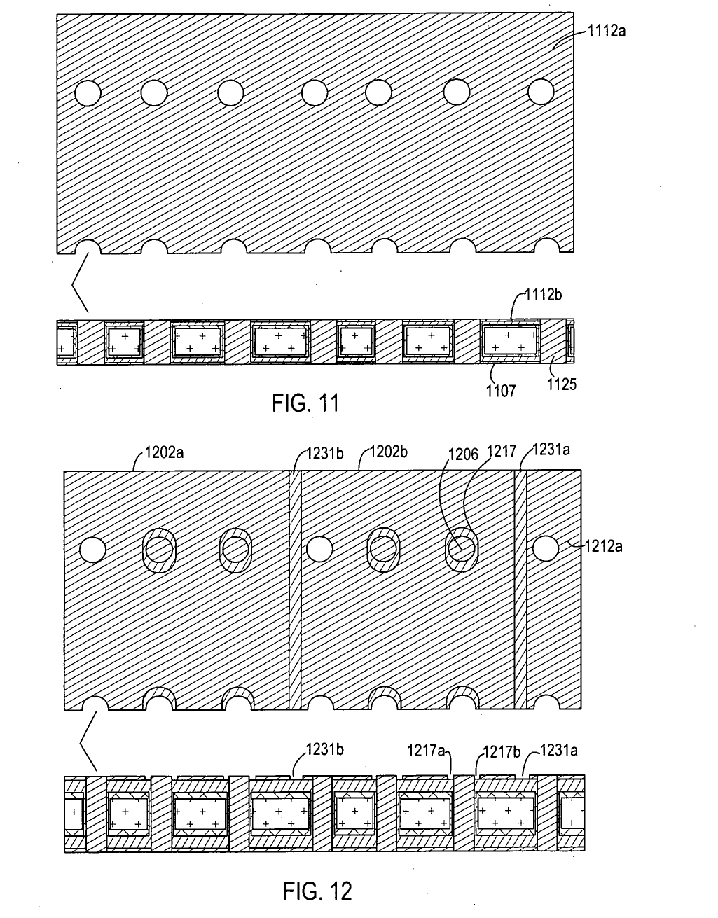

With reference to FIG. 7 a substrate 709a (top view) 709b (side view) having a desired conductive material is provided. FIG. 8 shows current collection via holes 806a (top view) 806b (side view) and serial interconnection holes 837a (top view) and 837b (side view) having a chosen size of between about 25-500 microns are formed therein to create the vias. In one embodiment series interconnection holes 837a are separated by 100 cm in both x and y directions. Current collections holes 806a are punched in between the serial connection holes at a separation of 1 cm in both the x and y directions. FIG. 9 shows an optional embodiment where the substrate 909a (top view) and 909b (side view) is coated with a top oxide layer 910a (top view) and 910b (side view) and a bottom oxide layer 908b (side view). The vias are coated internally 927 with the oxide layer material. When an aluminum substrate is used an anodization technique can be used to create an aluminum oxide layer (2-20 microns) on both surfaces and inside the holes thus creating an insulating surface and insulating holes. When a stainless steel substrate is used an aluminum oxide or silicon oxide layer may be deposited on the top and bottom surface of the substrate and along the hole walls to make sure the hole inside walls are completely covered with the oxide layer to create an insulating hole. FIG. 10 shows an optional embodiment where a barrier layer 1011a (top view) 1011b (side view) and 1030 (bottom barrier layer) is deposited next is deposited on the top oxide layer 1010 (side view) and the bottom oxide layer 1008 (side view) as well as inside the via 1021. FIG. 11 shows the addition of a bottom electrode 1112a (top view) and 1112b (side view) and a back metal electrode layer 1107 comprising a material such as Mo having a thickness of between 50-2,000 nm, more preferably 250-2,000 nm. In a preferred embodiment the material also coats the inside of the vias 1125. FIG. 12 shows that the metal electrode layer is scribed 1231a and 1231b to define cells adjacent cells 1202a and 1202b. In one embodiment the scribes are 100 cm apart to create a 100 cm×100 cm cell. Circumferential scribes 1217 (top view) 1217a and 121b (side view) are made around the current collection holes 1206 to isolate the current collection vias from the bottom electrode 1212a (top view). Preferably the scribe is approximately 100 microns wider than the inside diameter of the current collection holes.

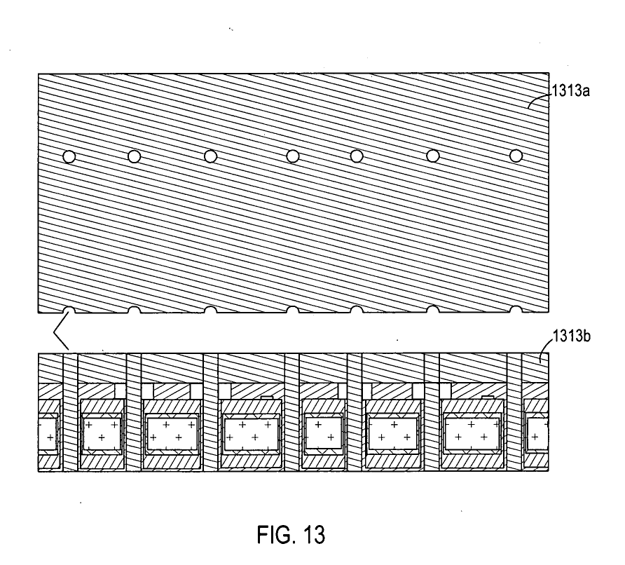

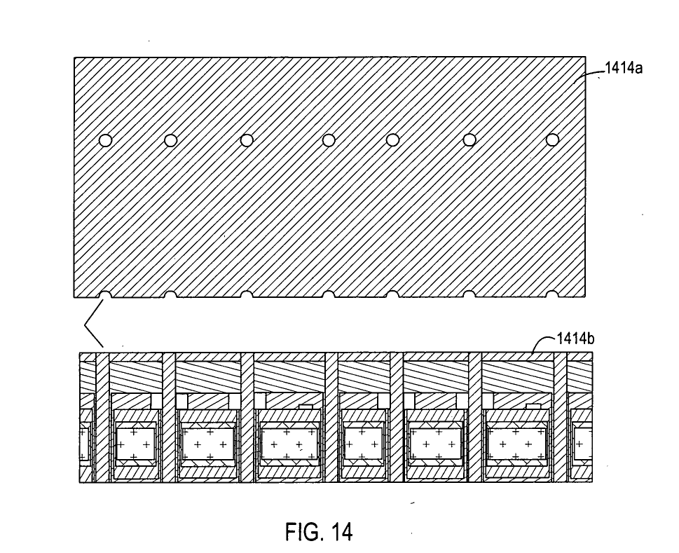

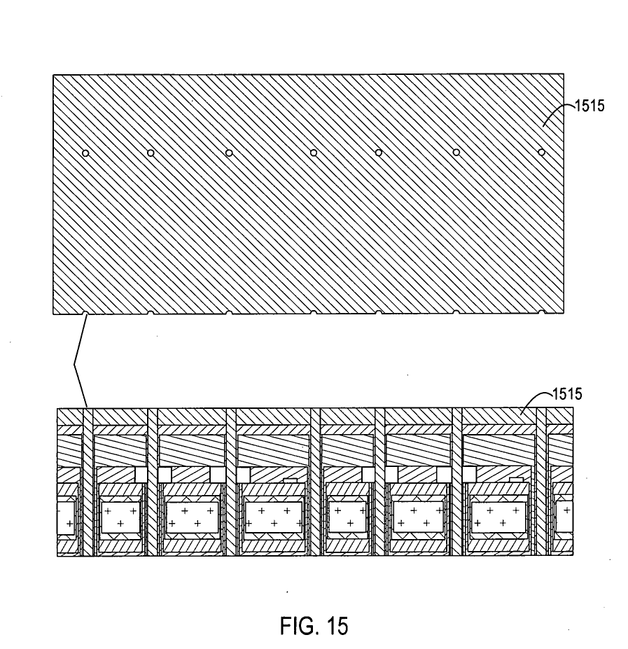

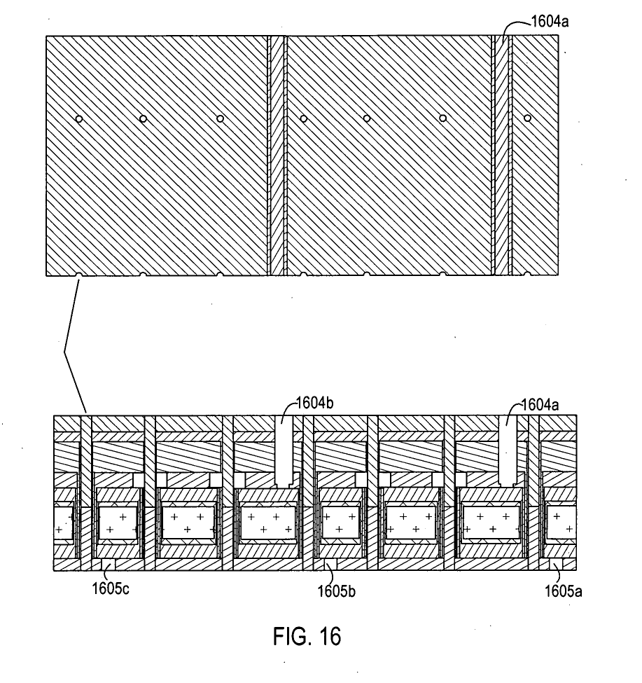

FIG. 13 shows the deposition of an absorber layer 1313a (top view) 1313b (bottom view) preferably comprising CdTe having a thickness of between about 1-10 microns. Optionally interface layers (not shown) such as ZnTe can be deposited at 500 nm thickness on Mo before depositing a CdTe absorber layer. FIG. 14 shows the deposition of a window layer 1414a (top view) 1414b (bottom view) preferably comprising CdS having a thickness of between about 50-200 nm. These layers are scribed just above the current collection holes to open up the contact area at these holes. In one non-limiting embodiment the scribe is 100 microns wider than the current collection holes. The size of the scribe is an obvious engineering variant depending on the materials used. FIG. 15 shows the deposition of a transparent conducting oxide layer 1515a (top view) 1515b (bottom view) preferably comprising ZnO and about 100-1000 nm. The transparent conducting oxide layer contacts the metal in the current collection holes and creates the back contact. FIG. 16 shows transparent conductor layer is scribed down to the barrier layer 1604a (top view) and 1604b (bottom layer) to isolate adjacent cells. Preferably the scribe is as close to the serial connection via as possible and the scribe is as narrow as possible. The back metal electrode is scribed 1605 to define the series connected cells with backside metal contact.

### EXAMPLE 5

### Thin-Film CdTe Solar Cell on Flexible Substrate with Serial Interconnect and Back Metal Contact with Coated Vias

In alternative embodiments of the present invention the vias are either coated or filled vias. In either case, the substrate may be insulating or electrically conductive. The photovoltaic layers are formed similarly as in any of Examples 1-4. A metal electrode layer, such as Mo, is deposited on the bottom or rear side of the substrate, at a thickness of 50-1,000 nm. The invention contemplates that this back metal layer be either the only electrode layer or part of one, two or more formed back electrode layers. This deposition of the metal layer will either partially coat the inner wall of the via or in another embodiment totally coat the inner wall of the via from top to bottom and circumferentially. In one embodiment the two metal layers on the bottom are the same. In another embodiment the two metal layers are different. The transparent conductor layer and the backside metal electrode are in electrical contact through the open vias at least part way such that they make electrical contact for current conduction. The transparent conductor layer at the top of the device is scribed to isolate individual photovoltaic cells for the series connection of adjacent cells.

### EXAMPLE 6

### Thin-Film CdTe Solar Cell on a Flexible Substrate with a Serial Interconnect Via and Back Metal Contacts with Different Size Vias

A photovoltaic device is manufactured similarly to that disclosed in Examples 1-4. The holes in the substrate are made of different diameters, shapes and/or both. This will enable some vias to be coated vias and others to be filled vias using the process described herein. In a non-limiting example series connection holes having a size between about 25-100 microns are punched in a substrate and current collection holes of size 100-500 microns are punched in a substrate. Series connection holes are separated by 10 cm in one direction and 100 cm in the orthogonal direction. Current collection holes are punched in between the serial connection holes at a separation of 1 cm in both x and y directions. In this embodiment the series connection holes are small enough to easily fill during a deposition process and create filled vias, whereas the current collection vias are larger and they won't fill, such that they form coated vias. The series connection filled vias allow more flexibility of the final isolation scribe location since those holes are not fully isolated from the TCO, thereby not requiring specific isolation.

### EXAMPLE 7

### Photovoltaic Device Architecture Using Different Cell Interconnect Pattern

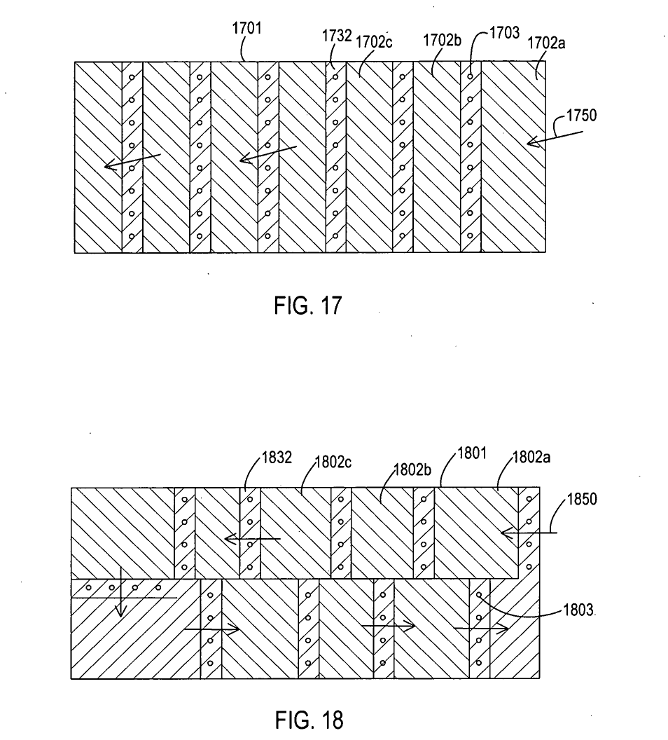

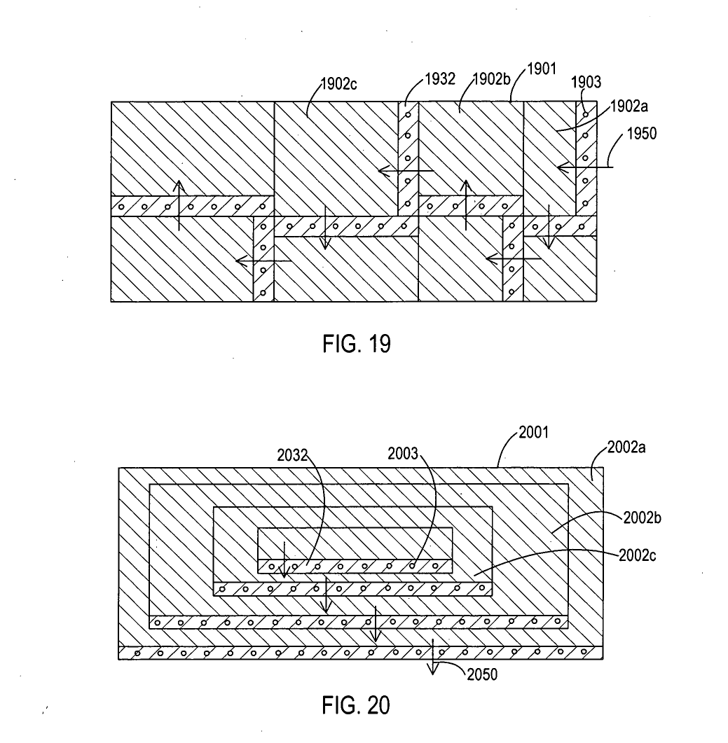

Photovoltaic cells employing the serial interconnect and current collection vias according to the present invention are capable of being connected in architectural patterns that ease manufacturing processing and costs. FIG. 17 shows a top view of a photovoltaic device 1701 having adjacent photovoltaic cells 1702a, 1702b and 1702c. Scribe 1732 through the transparent conductor layer isolates adjacent cells and isolates the serial interconnect vias 1703 from the transparent conductor electrode. Arrow 1750 shows the direction of current flow. FIG. 18 shows a top view of a photovoltaic device 1801 having adjacent photovoltaic cells 1802a, 1802b and 1802c connected in a tile circular pattern. Scribe 1832 through the transparent conductor layer isolates adjacent cells and isolates the serial interconnect vias 1803 from the transparent conductor electrode. Arrow 1850 shows the direction of current flow. FIG. 19 shows a top view of a photovoltaic device 1901 having adjacent photovoltaic cells 1902a, 1902b and 1902c connected in a tile snake pattern. Scribe 1932 through the transparent conductor layer isolates adjacent cells and isolates the serial interconnect vias 1903 from the transparent conductor electrode. Arrow 1950 shows the direction of current flow. FIG. 20 shows a top view of a photovoltaic device 2001 having adjacent photovoltaic cells 2002a, 2002b and 2002c connected in a annular pattern. Scribe 2032 through the transparent conductor layer isolates adjacent cells and isolates the serial interconnect vias 2003 from the transparent conductor electrode. Arrows 2050 shows the direction of current flow.

What is claimed is:

1. A photovoltaic device, comprising:
a plurality of photovoltaic cells,
said cells each independently comprise a transparent conducting electrode, a window layer, an absorber layer, a bottom electrode, a conductive substrate, and a back electrode,
wherein said bottom electrode and said back electrode are on opposite sides of the substrate.

2. A photovoltaic device as claimed in claim 1, wherein:
the substrate has plurality of vias extending through the substrate.

3. A photovoltaic device as claimed in claim 2, wherein:
the vias are insulated from the conducting substrate by a thin insulating layer inside the vias.

4. A photovoltaic device as claimed in claim 3, wherein:
the bottom electrode of a first cell and the back electrode of an adjacent cell are electrically connected through at least one first contact, wherein
said at least one first contact extends through the via, and
the first cell bottom electrode and said adjacent cell back electrode are not electrically connected through the conducting substrate.

5. A photovoltaic device as claimed in claim 4, wherein:
at least one first contact comprises a contiguous coating on a via wall.

6. A photovoltaic device as claimed in claim 4, wherein:
at least one first contact comprises a via filled with a conducting material.

7. A photovoltaic device as claimed in claim 4, wherein:
at least one cell is serially connected to an adjacent cell by at least one first contact, and
wherein said at least one first contact makes electrical contact between the bottom electrode of said at least one cell and the back electrode of an adjacent cell.

8. A photovoltaic device as claimed in claim 7, wherein:
the back electrode comprises a scribe near a first contact, wherein
said scribe extends through the back electrode, and
said adjacent cell comprises a scribe in the bottom electrode, wherein
said scribe is located near the first contact and extends through bottom electrode.

9. A photovoltaic device as claimed in claim 8, further comprising:
a first scribe through the transparent conducting electrode, wherein:
said first scribe is located near the first contact.

10. A photovoltaic device as claimed in claim 9, wherein:
said first scribe through the transparent conducting electrode extends through the window layer, absorber layer and the bottom electrode layer.

11. A photovoltaic device as claimed in claim 9, further comprising:
a second scribe through the transparent conducting electrode, wherein
said second scribe is located near the first contact and on an opposite side from said first scribe.

12. A photovoltaic device as claimed in claim 11, wherein:
said second scribe extends through the window layer and the absorber layer.

13. A photovoltaic device as claimed in claim 11, wherein:
said first and second scribes are substantially parallel to each other.

14. A photovoltaic device as claimed in claim 3, further comprising;
a plurality of second contacts, wherein
said plurality of second contacts each independently make parallel contact between the transparent conducting electrode and the back electrode, wherein
said plurality of second contacts are electrically insulated from the bottom electrode,
and the bottom electrode is not electrically connected to the back electrode.

15. A photovoltaic device as claimed in claim 14, wherein:
said second contact and said back electrode are in electrical contact through a contiguous coating on a via wall.

16. A photovoltaic device as claimed in claim 14, wherein:
said second contact and said back electrode are in electrical contact through a via filled with a conducting material.

17. A photovoltaic device as claimed in claim 1, further comprising:
a first contact to make a serial connection between at least two cells and a second contact to make a parallel connection within a cell.

18. A photovoltaic device as claimed in claim 1, further comprising:
at least one first contact and a plurality of second contacts, wherein:
said first contact and said second contacts each independently comprise a thin layer of conductive material that extends through the substrate.

19. A photovoltaic device as claimed in claim 1, further comprising:
at least one first contact and a plurality of second contacts, and
a thin insulating layer disposed inside the first contact and/or the second contact.

20. A photovoltaic device as claimed in claim 1, further comprising:
at least one first contact and a plurality of second contacts, and
a thin barrier layer disposed inside the first contact via and/or the second contact via.

21. A photovoltaic device as claimed in claim 1, wherein:
the absorber layer comprises a material chosen from the group consisting of Group IV materials, Group II-VI compounds, Group III-V compounds, Group I-III-VI compounds and organic polymers.

22. A photovoltaic device as claimed in claim 21, wherein:
the absorber layer comprises a material chosen from the group consisting of silicon, amorphous silicon, crystalline silicon, microcrystalline silicon, germanium and SiGe.

23. A photovoltaic device as claimed in claim 21, wherein:
the absorber layer comprises a compound chosen from the group consisting of CdTe, PbSe, PbTe, SnSe, SnS and SnTe.

24. A photovoltaic device as claimed in claim 21, wherein:
the absorber layer comprises a compound chosen from the group consisting of GaAs and InP.

25. A photovoltaic device as claimed in claim 21, wherein:
the absorber layer comprises a compound chosen from the group consisting of CIS and CIGS.

26. A photovoltaic device as claimed in claim 23, wherein:
the absorber layer comprises CdTe, and
the window layer comprises CdS.

27. A photovoltaic device as claimed in claim 1, wherein:
a plurality of photovoltaic cells are connected in a non-linear arrangement.

28. A photovoltaic device, comprising:
a plurality of photovoltaic cells,
said cells each independently comprise a transparent conducting electrode, a window layer, an absorber layer, a bottom electrode, a insulating substrate and a back electrode, wherein:
said bottom electrode and said back electrode are on opposite sides of the substrate.

29. A photovoltaic device as claimed in claim 28, wherein:
at least one cell is serially connected to an adjacent cell by at least one first contact, wherein:
said at least one first contact makes electrical contact between the bottom electrode of said at least one cell and the back electrode of an adjacent cell.

30. A photovoltaic device as claimed in claim 29, further comprising;
a plurality of second contacts,
said plurality of second contacts each independently make parallel contact between the transparent conducting electrode and the back electrode, wherein:
said plurality of second contacts are electrically insulated from the bottom electrode, and
the bottom electrode is not electrically connected to the back electrode inside a photovoltaic cell.

31. A process for making a photovoltaic device, comprising:
provide a substrate with a plurality of holes,
deposit a metal electrode layer on each side of the substrate to create a bottom and back electrode,
scribe a portion of the metal layer from the circumference of one or more of the holes to electrically isolate the hole from the bottom electrode,
scribe the bottom and back electrode longitudinally to define adjacent cells,
whereby the adjacent cells are in electrical contact with one another through at least one contact between a bottom electrode of one cell and a back electrode of an adjacent cell through at least one hole, said hole positioned between the bottom scribe and the back electrode scribe, and further comprising,
deposit an absorber layer, and
deposit a transparent conductor layer.

32. A process for making a photovoltaic device according to claim 31, further comprising:
scribing the transparent conducting electrode longitudinally across a cell on one side of a series interconnect via, and
scribing the transparent conducting electrode longitudinally across a cell on the opposite side of the same series interconnect via, wherein:
said scribes are in close proximity to the series interconnect via, and said scribes remove the TCO layer.
